(19) United States
(12) Patent Application Publication
(10) Pub. No.: US 2003/0112587 A1
(43) Pub. Date: Jun. 19, 2003

(54) Hermetically sealed housing

(75) Inventors: Jens Krause, Rahden (DE); Thomas Heimann, Espelkamp (DE)

Correspondence Address: HAYES SOLOWAY P.C., Attn: Norman P. Soloway, 130 W. Cushing Street, Tucson, AZ, 85701, US

(73) Assignee: HARTING Automotive GmbH & Co. KG

(21) Appl. No.: 10/316,740

(22) Filed: Dec. 11, 2002

(30) Foreign Application Priority Data
Dec. 17, 2001 (DE) 201 20 373.1

(51) Int. Cl. H05K 5/00

(52) U.S. Cl. 361/679

(57) ABSTRACT

A hermetically sealed housing for power electronics comprises a tank which is made of metal and has at least one side wall provided with at least one cut-out, and a cover adapted to be fitted to the housing so as to hermetically seal off the housing. The housing further comprises an insulating plate made of plastic and provided with at least one current lead-through. The insulating plate is fastened to the side wall such that the current lead-through projects through the cut-out. A permanently elastic sealing and gluing compound is arranged across a large surface area between the insulating plate and the side wall of the housing.

### TECHNICAL FIELD

The invention relates to a hermetically sealed housing for power electronics.

### BACKGROUND OF THE INVENTION

Conventional housings of this type usually are provided with an evaporation cooling and comprise a tank which is made of metal and has at least one side wall provided with at least one cut-out, a cover adapted to be fitted to the housing so as to hermetically seal off the housing, and an insulating plate made of plastic and provided with at least one current lead-through, the insulating plate being fastened to the side wall such that the current lead-through projects through the cut-out.

Such a housing is known from German Utility Model 200 20 270. It serves the purpose to reliably carry off heat loss of the power electronics, for preventing the power electronics from overheating. Here, the term “power electronics” means an assembly of at least one electronic component in which high electric power is converted, so that a large amount of heat loss is produced. According to a preferred embodiment of the housing according to the invention, the power electronics is an inverter of a so-called starter generator, which combines the components starter motor and electric generator that hitherto have been provided so as to be separate from each other.

With the evaporation cooling, the components of the power electronics are directly surrounded by a cooling liquid received in the housing in which the power electronics is arranged, too. It is preferred that the components that are to be cooled are designed so as to have no housing, so that the cooling liquid directly contacts those portions of the component where the heat loss is produced. In the case of semiconductor chips, it is the surface area of the silicon chips that is in direct contact with the cooling liquid.

The cooling liquid is selected such that during operation of the power electronics it evaporates at those portions of the components in which the heat loss is generated. The resultant vapor bubbles rise and are condensed on cooler portions of the housing, in particular on the cover, so that it again is available as cooling liquid for a further vaporization process. This cooling method is particularly effective, because a much higher amount of energy is taken up when the cooling liquid makes the phase transition from liquid to vapor than this would be the case with a pure liquid cooling.

The problem with an evaporation cooling is that the temperature of the cooling liquid rises whenever the power electronics is set into operation; an increasing internal pressure in the housing is bound to happen with this. This cyclic pressure load means a considerable mechanical stress on the current lead-through passing the wall of the housing. If such a housing is provided for the use in motor vehicles, it has to be ensured that the housing is tight even after a service life of 15 years, because otherwise a cooling of the power electronics could not be guaranteed.

With the known housing, a seal in the form of an O-ring is provided on the periphery of the insulating plate, this O-ring being arranged in a groove in the insulating plate an resting against the side wall of the housing. The groove in the insulating plate, however, has to be manufactured with very high accuracy and a very high surface quality if the required reliable sealing is to be maintained for a long service life.

The object of the invention is to provide a housing for an evaporation cooling of a power electronics, in which the current lead-through passing the side wall of the tank can be manufactured with less expenditure.

### BRIEF SUMMARY OF THE INVENTION

According to the invention, a hermetically sealed housing for power electronics comprises a tank which is made of metal and has at least one side wall provided with at least one cut-out, and a cover adapted to be fitted to the housing so as to hermetically seal off the housing. The housing further comprises an insulating plate made of plastic and provided with at least one current lead-through. The insulating plate is fastened to the side wall such that the current lead-through projects through the cut-out. A permanently elastic sealing and gluing compound is arranged across a large surface area between the insulating plate and the side wall of the housing. The invention is based on the knowledge that—in spite of the difference in the thermal expansion of the side wall of the housing on the one hand and that of the insulating plate on the other—it is possible to use a full-surface gluing between the insulating plate and the side wall of the housing. Due to the large gluing surface area available, the glued joint has such a strength that the tightness between the insulating plate and the side wall of the housing is not impaired even after a very high number of operating cycles. Hitherto, however, it was assumed owing to the differing heat expansion behavior that it is required to use an O-ring for sealing purposes, which O-ring offers a larger range for a relative movement between the two parts. If there is used the large-surface gluing provided according to the invention, however, then it is not necessary any longer to keep up with such high demands with respect to surface quality of the insulating plate, with the result of decreasing production costs.

The tank preferably is made of steel, aluminum or an aluminum alloy; the permanently elastic sealing and gluing compound is of the type as is known from aircraft construction for gluing two aluminum alloys with each other. Now it has been discovered that such a sealing and gluing compound is suitable even if different materials are to be glued with each other, namely a plastics plate and a sheet metal plate. The permanently elastic sealing and gluing compound is temperature-resistant up to 160° C. at an internal pressure of up to 3 bar. It is also resistant against fluorocarbon which is preferably used as cooling liquid. Such a suitable sealing and gluing compound preferably contains polysulfide.

According to the preferred embodiment of the invention, a depot groove is provided on the side of the insulating plate facing the side wall of the housing, the depot groove extending along the outer edge of the insulating plate. The depot groove can have a depth of between 0.5 and 1.5 mm. Due to its large cross-section, the sealing and gluing compound present in the depot groove works in the nature of a sealing strip having a rectangular cross-section and being comparably flexible.

According to the preferred embodiment, a plurality of spacers is provided on the side of the insulating plate facing the side wall of the housing, which rest against the side wall. The spacers which can be configured as pyramid-shaped protrusions with a height of between 0.1 and 0.5 mm ensure a constant thickness of the permanently elastic sealing and gluing compound. The protrusions are distributed across the insulating plate in such a manner that the pressing force, which is applied at a later point in time when insulating plate and side wall are glued together, does not result in the insulating plate being bent. For that reason, the spacers do not have to be uniformly distributed across the entire surface of the insulating plate, they rather can be limited to those portions to which the pressing force will be applied. Using spacers in the shape of a pyramid has the advantage that the tip of the pyramid reliably penetrates the gluing layer applied and mechanically engages the side wall due to the high resultant surface pressure, so that the insulating plate cannot float on the gluing layer which would result in a misalignment.

There can be provided a plurality of rivets by means of which the insulating plate is fastened to the side wall. The rivets, however, are not required for mechanically holding the insulating plate on the side wall during use of the housing; the insulating plate rather being pressed automatically against the side wall due to the overpressure in the interior of the housing occurring during operation. The rivets merely have the function of applying the pressing force between insulating plate and side wall of the housing, when the housing complete with the insulating plate has been removed from the pressing tool which initially applies the pressing force. If rivets were not used, the housing had to remain in the pressing tool until the sealing and gluing compound has cured.

The insulating plate is preferably made of a semi-crystalline and capillary inactive plastic, in particular PPS which in addition can be reinforced with fibers. In this way the required strength and diffusion tightness is obtained.

Advantageous designs of the invention will be apparent from the subclaims.

### BRIEF DESCRIPTION OF THE DRAWINGS

FIG. 1 shows in a perspective view a housing according to the invention;

FIG. 2 shows in a perspective view a tank for the housing of FIG. 1;

FIG. 3 is a side view of the housing of FIG. 2;

FIG. 4 shows on an enlarged scale the detail IV of FIG. 3;

FIG. 5 is a further side view of the housing of FIG. 2;

FIG. 6 shows in a perspective view the inside of the side wall of the housing, provided with the insulating plate;

FIG. 7 is a section along plane VII-VII of FIG. 6; and

FIG. 8 shows on an enlarged scale the detail VIII of FIG. 7.

### DETAILED DESCRIPTION OF THE PREFERRED EMBODIMENT

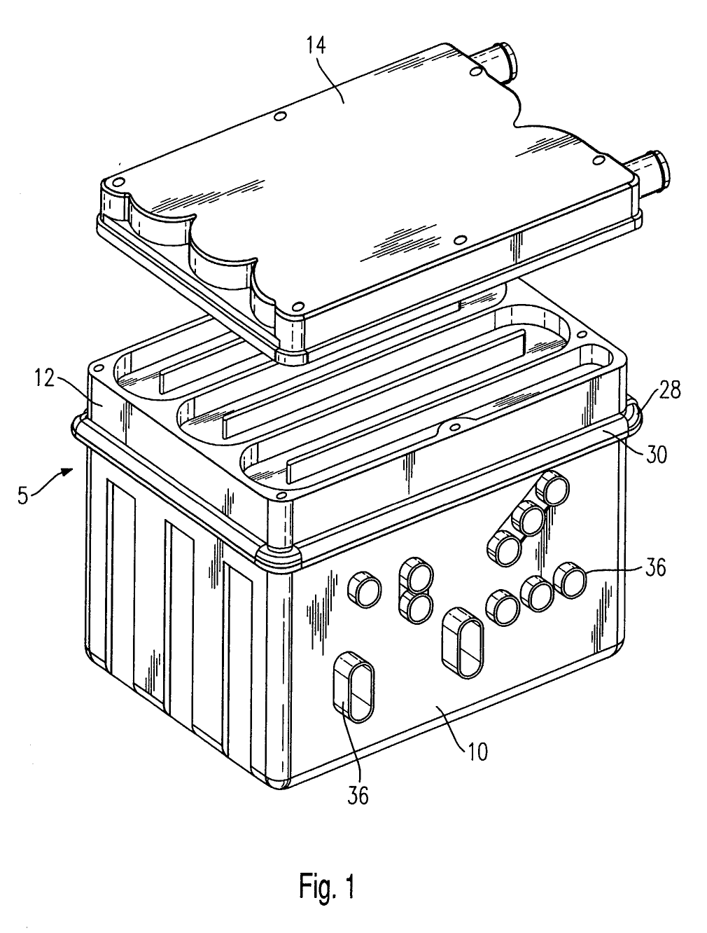

In FIG. 1 there is shown a housing 5 comprising a tank 10, a cover 12 as well as a covering 14 placed on the cover.

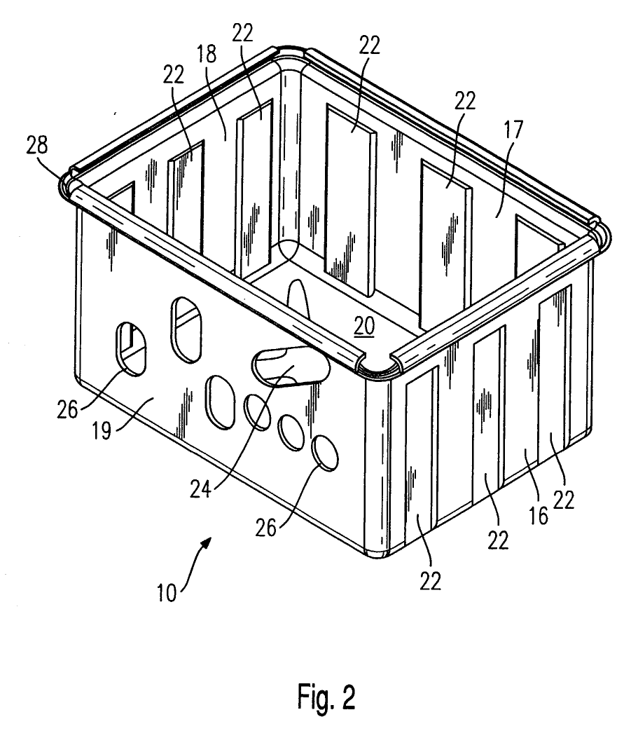

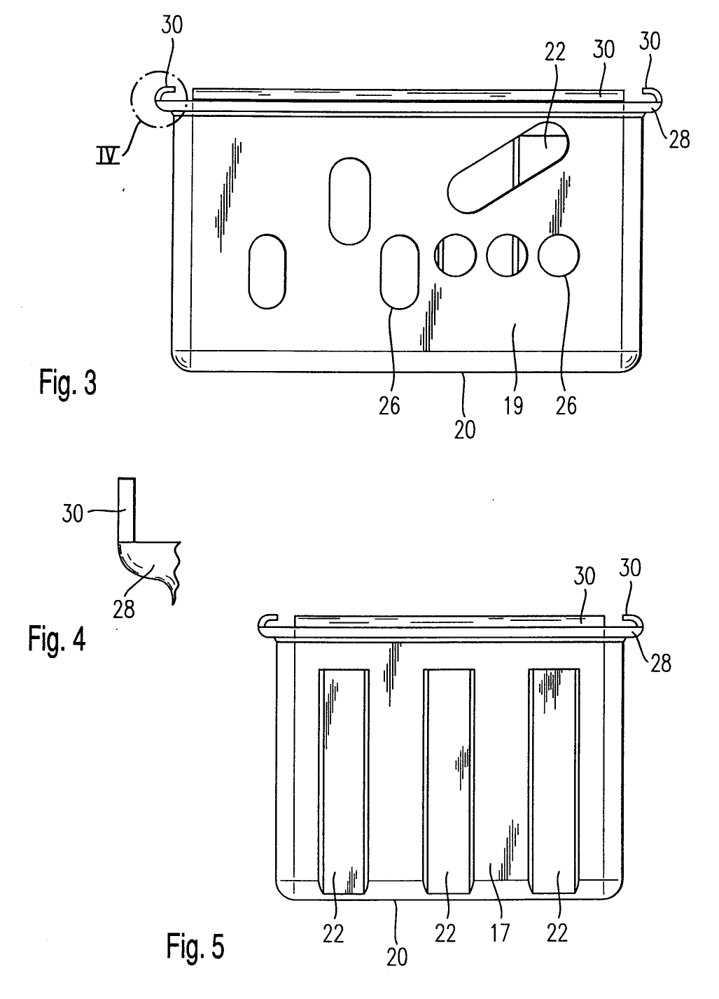

The tank 10 (see also FIGS. 2 to 5) is a deep-drawn sheet metal part with a wall thickness of about 2.5 mm and has a rectangular cross-section with four side walls 16, 17, 18, 19 and a base 20. Alternatively, a tank could be used the walls and base of which consist of an aluminum alloy and are connected to each other by welding. The side walls 16, 17, 18 each have three beads 22 which starting from the base 20 extend upwards. The base 20 is provided with a cross-bead 24. The planar side wall 19 without any bead comprises several cut-outs 26 the function of which will be explained below.

On its side facing away from the base 20, the tank 10 has a surrounding edge 28 configured in the nature of a collar projecting beyond the side walls in outward direction. In the region of each of the side walls, the edge 28 is provided with a bending tab 30 which is shown in FIG. 4 in its initial state and which are shown in FIGS. 2, 3 and 5 in their bent state into which they are brought for fastening the cover to the tank.

The cover 12 provided for being placed on the tank 10 is a cast part made of an aluminum alloy. Basically, it would be possible to bring a suitably cast blank to its final shape by means of extrusion or a similar processing technology.

A covering 14 (see FIG. 1) made of plastic is placed on the cover 12. The covering 14 is provided with two connecting sleeves which can be connected to the cooling pipes for guiding a suitable cooling medium through a cooling conduit in the cover 12.

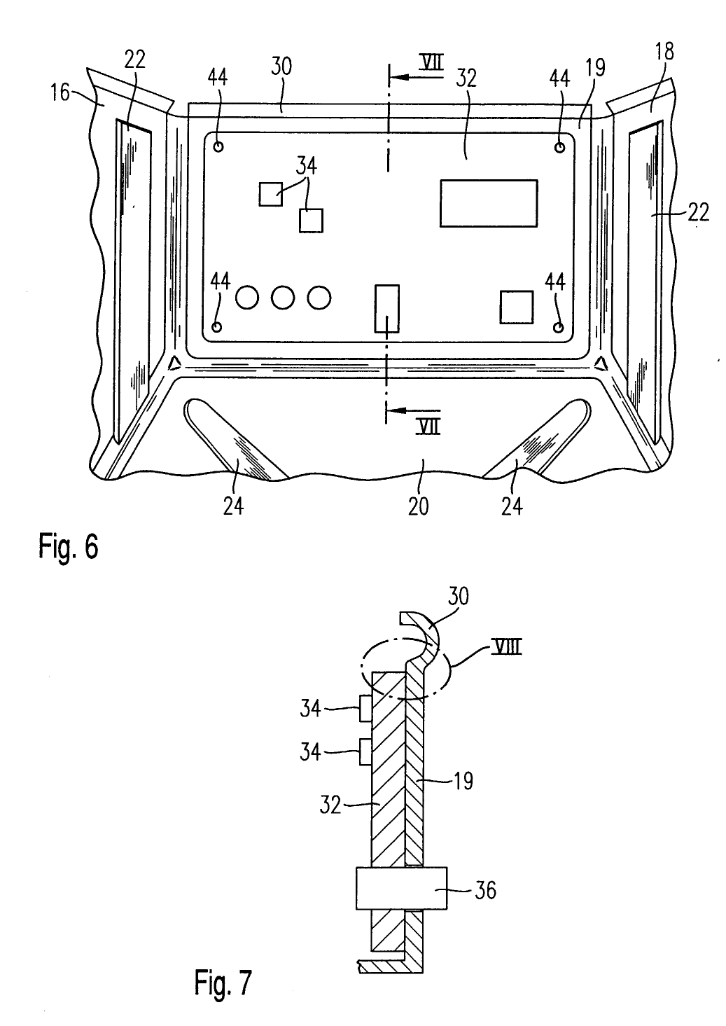

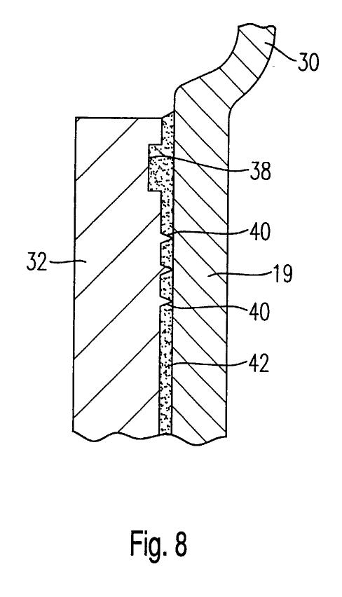

In FIG. 6 there is shown an insulating plate 32 which is rectangular and the dimensions of which correspond approximately to those of the side wall 19. The insulating plate 32 consists of an insulating plastics material, for example a semi-crystalline and diffusion-tight plastic such as PPS, and carries power electronics which are shown here only schematically by means of some components 34. The insulating plate 32 is provided with a plurality of current lead-throughs 36 the arrangement and dimensions of which correspond to the dimensions and arrangement of the cut-outs 26 in the side wall 19 of the tank. The current lead-throughs 36 make it possible to electrically connect the power electronics 34 in the vehicle. On its side facing the side wall 19 of the tank, the insulating plate 32 is provided with a depot groove 38 (see FIG. 8) which has a depth of approximately 1 mm as well as a rectangular cross-section. The depot groove 38 extends along the entire edge of the insulating plate 32 such that it is closed. Within the region surrounded by the depot groove 38, a plurality of spacers 40 is formed on the side of the insulating plate 32 facing the side wall 19 of the housing, these spacers having the shape of sharp pyramids. The spacers each have a height of approximately 0.3 mm. The insulating plate 32 provided with the depot groove 38 and the spacers 40 can be given the shape by means of a suitable forming mold with low expenditure.

For sealing off between the side wall 19 of the tank and the insulating plate 32, and hence for sealing the cut-outs 26, there is used a permanently elastic sealing and gluing compound 42 which is arranged across a large surface area between the insulating plate and the side wall 19 of the housing. A gluing agent containing polysulfide is particularly suitable for being used as permanently sealing and gluing compound; such gluing agent being known from aircraft construction for joining two components made of an aluminum alloy.

For mounting the insulating plate 32 to the side wall 19 of the housing, the permanently elastic sealing and gluing compound is either directly applied across a large surface area onto the side wall of the housing or that side of the insulating plate 32 which faces the side wall of the housing. Next, the insulating plate 32 is pressed against the side wall 19, with the spacers 40 preventing the sealing and gluing compound 42 being completely squeezed out of the gap between the insulating plate and the side wall 19; these spacers also ensure a constant thickness of the layer.

So that the tank 10 of the housing with the insulating plate 32 do not need to remain in a press until the sealing and gluing compound 42 has cured, the insulating plate 32 can be fastened to the side wall 19 of the tank 10 by several rivets 44 (see FIG. 6). The rivets, however, are not required for the mechanical connection between the insulating plate 32 and the side wall 19 of the tank 10 if the permanently elastic sealing and gluing compound has reached the cured state.

When the insulating plate 32 with the power electronics 34 thereon has been mounted, the tank 10 is filled with a cooling liquid which can be almost any liquid with a low boiling point. Fluorohydrocarbon is particularly suitable. As a final step, the cover 12 is mounted to the tank 10, this cover being pressed against the edge 28 of the tank by means of the bending tabs 30.

1. A hermetically sealed housing for power electronics, said housing comprising a tank which is made of metal and has at least one side wall provided with at least one cut-out, a cover adapted to be fitted to said housing so as to hermetically seal off said housing, and an insulating plate made of plastic and provided with at least one current lead-through, said insulating plate being arranged at said side wall such that said current lead-through projects through said cut-out and being fastened to said side wall by a permanently elastic sealing and gluing compound which is arranged across a large surface area between said insulating plate and said side wall of said housing.

2. The housing according to claim 1, wherein said tank is made of steel.

3. The housing according to claim 1, wherein said tank is made of one of aluminum and aluminum alloy.

4. The housing according to claim 1, wherein a depot groove is provided on the side of said insulating plate facing said side wall of said housing, said depot groove extending along an outer edge of said insulating plate.

5. The housing according to claim 1, wherein said depot groove has a depth of between 0.5 and 1.5 mm.

6. The housing according to claim 1, wherein a plurality of spacers is provided on said side of said insulating plate facing said side wall of said housing, which rest against said side wall.

7. The housing according to claim 6, wherein said spacers are a plurality of protrusions in the shape of a pyramid.

8. The housing according to claim 7, wherein said spacers have a height of between 0.1 and 0.5 mm.

9. The housing according to claim 1, wherein a plurality of rivets is provided by means of which said insulating plate is fastened to said side wall.

10. The housing according to claim 1, wherein said insulating plate is made of a semi-crystalline, capillary inactive plastic.

11. The housing according to claim 1, wherein said insulating plate is made of a fiber-reinforced plastic.

12. The housing according to claim 1, wherein said insulating plate is made of PPS.

13. The housing according to claim 1, wherein said permanently elastic sealing and gluing compound contains polysulfide.
